(19) United States
(12) Patent Application Publication
(10) Pub. No.: US 2006/0180859 A1
(43) Pub. Date: Aug. 17, 2006

(54) Metal gate carbon nanotube transistor

(76) Inventors: Marko Radosavljevic, Beaverton, OR (US); Amlan Majumdar, Portland, OR (US); Suman Datta, Beaverton, OR (US); Jack Kavalieros, Portland, OR (US); Brian S. Doyle, Portland, OR (US); Justin K. Brask, Portland, OR (US); Robert S. Chau, Beaverton, OR (US)

Correspondence Address: TROP PRUNER & HU, PC, 1616 S. VOSS ROAD, SUITE 750, HOUSTON, TX, 77057-2631, US

(21) Appl. No.: 11/059,184

(22) Filed: Feb. 16, 2005

(51) Int. Cl. H01L 27/12; H01L 21/84

(52) U.S. Cl. 257/347; 257/353; 438/149; 257/E29.242

(57) ABSTRACT

A top metal gate carbon nanotube transistor may be provided which has acceptable electrical characteristics. The transistor may be formed over a structure including a semiconductor substrate made of an epitaxial layer and covered with an insulating layer. The carbon nanotubes may be deposited thereover, source and drains defined, and a metal gate electrode applied over a high dielectric constant gate dielectric. The processing may be such that the carbon nanotubes are protected from high temperature processing and excessively oxidizing atmospheres.

### BACKGROUND

This invention relates generally to carbon nanotube transistors.

Carbon nanotube transistors may be advantageous because carbon nanotubes have excellent electrical properties with both holes and electrons. For example, carbon nanotubes show very high theoretical values for mobility.

Single walled semiconducting nanotubes, having diameters between 1.5 and 2 nanometers, exhibit energy bandgaps of from 0.65 to 0.4 eV. With top gate carbon nanotube transistors having metal gates and scaled dielectrics (e.g., less than 20 Angstroms), poor electrical characteristics may be exhibited, such as high gate current. In addition, the nucleation of oxides on the carbon nanotubes is poorly understood and poorly controlled.

Thus, there is a need for better ways to make metal gate carbon nanotube transistors.

### BRIEF DESCRIPTION OF THE DRAWINGS

FIG. 1 is an enlarged, cross-sectional view at an early stage of manufacture in accordance with one embodiment of the present invention;

FIG. 2 is an enlarged, cross-sectional view at a subsequent state of manufacture in accordance with one embodiment of the present invention;

FIG. 3 is an enlarged, cross-sectional view at a subsequent state of manufacture in accordance with one embodiment of the present invention; and

FIG. 4 is an enlarged, cross-sectional view at a subsequent stage of manufacture in accordance with one embodiment of the present invention.

### DETAILED DESCRIPTION

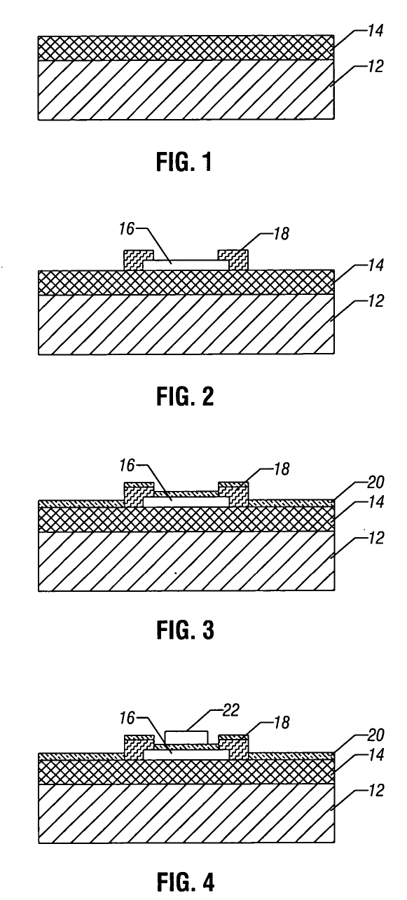

Referring to FIG. 1, a semiconductor substrate 12 may be a semiconductor wafer in one embodiment of the present invention. For example, a blanket epitaxial wafer may be used as the substrate 12. The substrate 12 may be covered by an insulating layer 14. The layer 14 serves to electrically isolate the substrate 12 from an overlying carbon nanotube channel. For example, the insulating layer 14 may be formed of oxides such as silicon dioxide or metal oxides such as hafnium or lanthanum oxide. In general, high dielectric constant materials may also be utilized. These materials may have dielectric constants greater than 10.

The resulting structure may have characteristics similar to those of silicon over insulator (SOI) substrates. Particularly, the insulating layer 14 may act like a buried oxide in SOI technologies in some embodiments.

Referring to FIG. 2, the carbon nanotubes 16 may then be positioned over the insulating layer 14. The carbon nanotubes may be deposited from solution, for example, using Langmuir-Blodgett or self-assembly-techniques. Alternatively, the carbon nanotubes may be directly grown on the insulating layer 14 over the substrate 12. In some embodiments, the carbon nanotubes 16 may be single walled carbon nanotubes.

The source and drain 18 may be formed as metal contacts extending over the carbon nanotubes 16. They may be formed by depositing a suitable metal layer and using lithography, metallization, and lift-off. By avoiding the use of etching, the carbon nanotubes 16 may be protected from etch chemistries to which they may be susceptible. Suitable metals for the source drain 18 include high workfunction materials (such as platinum) for PMOS transistors and low workfunction materials (such as aluminum) for NMOS transistors.

Referring to FIG. 3, a high dielectric constant layer 20 may then be deposited, for example, by atomic layer deposition. Suitable materials for the layer 20 include metal oxides such as hafnium or lanthanum oxide. The layer 20 may have a thickness of from 10 Angstroms to 5 50 Angstroms in some embodiments.

Prior to depositing the layer 20, a pre-clean may be completed. The use of oxidizing agents may be avoided in some cases, or severely limited, to reduce burning of the carbon nanotubes 16. In addition, deposition temperatures may be limited to below 400 degrees C. to avoid adversely affecting the carbon nanotubes 16.

Finally, referring to FIG. 4, a metal gate 22 may be deposited and patterned. Temperatures above 400 degrees C. are advantageously avoided. Lithography, metallization, and lift-off techniques may be used again in order to protect the carbon nanotubes 16 in some embodiments. The lack of high temperature processing allows the metal workfunction to be tuned for specific p-channel applications. Suitable materials for p-channel devices include platinum. The thickness of the metal gate 22 may be from 100 to 1000 Angstroms in some embodiments.

In general, after the carbon nanotubes 18 are deposited in FIG. 2, it is advantageous to avoid exposing the structure to temperatures above 400 degrees C. Moreover, it is preferable to limit the processing ambient atmosphere to those atmospheres having an oxygen content of less than 100 ppm.

In some embodiments, the excellent mobility of carbon nanotube channels may be combined with excellent gate coupling, achieved by high dielectric constant layer 20. In addition, when selecting the gate metal, workfunction engineering may be subject to process and performance optimization.

While the present invention has been described with respect to a limited number of embodiments, those skilled in the art will appreciate numerous modifications and variations therefrom. It is intended that the appended claims cover all such modifications and variations as fall within the true spirit and scope of this present invention.

What is claimed is:

1. A method comprising:
forming a layer of carbon nanotubes;
providing an insulating layer over said carbon nanotubes; and
providing a metal gate electrode over said insulating layer.

2. The method of claim 1 including forming a transistor at a temperature less than 400 C.

3. The method of claim 1 including forming a transistor using environments having an oxygen content less than 100 ppm.

4. The method of claim 1 including forming metal contacts over said nanotubes.

5. The method of claim 4 including using a lift off technique to form said contacts.

6. The method of claim 1 including forming said layer of carbon nanotubes over a substrate including an epitaxial silicon layer covered by oxide.

7. The method of claim 1 including forming the insulating layer with a dielectric constant greater than ten.

8. The method of claim 1 including forming said insulating layer over a substrate in the form of a blanket epitaxial wafer.

9. An integrated circuit comprising:
a semiconductor substrate;
an insulating layer over said substrate;
a layer of carbon nanotubes over said insulating layer; and
a metal gate electrode over said insulating layer.

10. The circuit of claim 9 including a metal source drain over said carbon nanotubes.

11. The circuit of claim 9 wherein said substrate includes an epitaxial silicon layer.

12. The circuit of claim 9 wherein said insulating layer has a dielectric constant greater than ten.

13. The circuit of claim 9 including a PMOS transistor.

14. The circuit of claim 9 including an NMOS transistor.

15. The circuit of claim 9 wherein said carbon nanotubes are single walled carbon nanotubes.

16. An integrated circuit comprising:
a semiconductor substrate;
an insulating layer over said substrate, said insulating layer having a dielectric constant greater than ten;
a layer of carbon nanotubes over said insulating layer;
a metal gate electrode over said insulating layer; and
a metal source drain over said insulating layer.

17. The circuit of claim 16 wherein said substrate includes an epitaxial silicon layer.

18. The circuit of claim 16 wherein said circuit includes a PMOS transistor.

19. The circuit of claim 16 wherein said circuit includes an NMOS transistor.

20. The circuit of claim 16 wherein said carbon nanotubes are single walled carbon nanotubes.
